(19) United States
(12) Patent Application Publication
(10) Pub. No.: US 2026/0372131 A1
(43) Pub. Date: Nov. 19, 2026

(54) SEMICONDUCTOR PACKAGE INCLUDING THIN FILM AND METHOD OF MANUFACTURING SAME

(71) Applicant: SAMSUNG ELECTRONICS CO., LTD., Suwon-si (KR)

(72) Inventor: Myungsam KANG, Suwon-si (KR)

(73) Assignee: SAMSUNG ELECTRONICS CO., LTD., Suwon-si (KR)

(21) Appl. No.: 19/435,053

(22) Filed: Dec. 29, 2025

(30) Foreign Application Priority Data
May 19, 2025 (KR) 10-2025-0064568

(51) Int. Cl. H10W 70/63; H10W 70/60; H10W 70/685; H10W 90/10; H10W 40/20; H10W 70/692; H10W 90/00

(52) U.S. Cl. CPC H10W 70/635; H10W 70/618; H10W 70/686; H10W 90/10; H10W 40/235; H10W 70/692; H10W 90/724

(57) ABSTRACT

A semiconductor package, including a glass substrate including a cavity region, a through via penetrating the glass substrate, a thin film layer covering at least a portion of a surface of the glass substrate, a redistribution substrate disposed on the thin film layer, and a semiconductor chip disposed on the redistribution substrate. The thin film layer may include an opening portion exposing a top surface of the through via and a bottom surface of the through via. A diameter of the opening portion may be equal to or less than a diameter of the through via.

### CROSS-REFERENCE TO RELATED APPLICATIONS

This application claims the benefit of Korean Patent Application No. 10-2025-0064568, filed on May 19, 2025, in the Korean Intellectual Property Office, the disclosure of which is incorporated herein by reference in its entirety.

### BACKGROUND

### 1. Field

Example embodiments relate to a semiconductor package.

### 2. Description of the Related Art

A semiconductor package is an implementation of an integrated circuit chip in a form suitable for use in electronic products. Generally, a semiconductor package mounts a semiconductor die onto a printed circuit board (PCB) and electrically connects the semiconductor die and the PCB by using a bonding wire or a bump. With the development of the electronics industry, various studies are ongoing to improve the reliability and durability of semiconductor packages.

### SUMMARY

Aspects provide a semiconductor package with improved durability and reliability.

Aspects provide reduction of delamination and cracking of a glass substrate by securing adhesion between a glass substrate and a redistribution substrate through a thin film layer that covers at least a portion of a surface of the glass substrate.

Technical goals of the present disclosure are not limited to the aforementioned technical goals, and other unstated technical goals may be clearly understood by those who skilled in the art from example embodiments below.

According to aspects, there is provided a semiconductor package, comprising a glass substrate including a cavity region, a through via penetrating the glass substrate, a thin film layer covering at least a portion of a surface of the glass substrate, a redistribution substrate disposed on the thin film layer, and a semiconductor chip disposed on the redistribution substrate. The thin film layer may include an opening portion exposing a top surface of the through via and a bottom surface of the through via. A diameter of the opening portion may be equal to or less than a diameter of the through via.

According to aspects, there is provided a semiconductor package, comprising a lower redistribution substrate, a glass substrate disposed on the lower redistribution substrate and including a cavity region, a through via penetrating the glass substrate, a thin film layer covering at least a portion of a surface of the glass substrate, a bridge die disposed within the cavity region, an upper redistribution substrate disposed on the thin film layer and the bridge die, a semiconductor chip disposed on the upper redistribution substrate, and a mold layer covering at least a portion of the lower redistribution substrate, the glass substrate, the bridge die, the upper redistribution substrate, and the semiconductor chip. A portion of the thin film layer may be disposed on a side wall of the cavity region. The thin film layer may include an opening portion exposing at least a portion of the through via.

According to aspects, there is provided a semiconductor package, comprising a base substrate, a lower redistribution substrate disposed on the base substrate, a glass substrate disposed on the lower redistribution substrate and including a cavity region, a through via penetrating the glass substrate, a thin film layer disposed on a surface of the glass substrate and covering at least a portion of the glass substrate, a wiring layer disposed on the thin film layer and spaced apart from the through via in a direction parallel to a surface of the glass substrate, a bridge die disposed within the cavity region, an upper redistribution substrate disposed on the thin film layer and the bridge die, a semiconductor chip disposed on the upper redistribution substrate, a mold layer covering at least a portion of the lower redistribution substrate, the glass substrate, the bridge die, the upper redistribution substrate, and the semiconductor chip, and a heat dissipation member covering at least one of a top surface of the base substrate, the semiconductor chip, and the mold layer. The thin film layer may include an opening portion exposing at least a portion of a surface of the through via.

Details of other example embodiments are included in the detailed description and drawings.

### BRIEF DESCRIPTION OF THE FIGURES

These and/or other aspects, features, and advantages of the inventive concept will become apparent and more readily appreciated from the following description of example embodiments, taken in conjunction with the accompanying drawings of which:

FIG. 1 is a top plan view of a semiconductor package according to example embodiments of the present disclosure;

FIG. 2A is an exemplary diagram illustrating a cross section taken along I-I' line of FIG. 1;

FIG. 2B is an enlarged view illustrating part A of FIG. 2A;

FIG. 2C is a diagram looking from a third direction focusing on an opening portion of a thin film layer and a through via;

FIG. 3 is a semiconductor package according to example embodiments of the present disclosure and an enlarged view illustrating part A of FIG. 2A;

FIG. 4 is a semiconductor package according to example embodiments of the present disclosure and an enlarged view illustrating part A of FIG. 2A;

FIG. 5A is a semiconductor package according to example embodiments of the present disclosure and an enlarged view illustrating part A of FIG. 2A;

FIG. 5B is a diagram looking from a third direction focusing on an opening portion of a thin film layer and a through via;

FIG. 6 is a semiconductor package according to example embodiments of the present disclosure and an exemplary diagram illustrating a cross section taken along I-I' line of FIG. 1;

FIG. 7 is a semiconductor package according to example embodiments of the present disclosure and an exemplary diagram illustrating a cross section taken along I-I' line of FIG. 1;

FIG. 8 is a semiconductor package according to example embodiments of the present disclosure and an exemplary diagram illustrating a cross section taken along I-I' line of FIG. 1;

FIGS. 9A, 9B, 9C, 9D, 9E, 9F, and 9G are exemplary diagrams illustrated according to a process sequence to explain a method of manufacturing some elements of a semiconductor package according to example embodiments of the present disclosure.

FIGS. 9H, 9I, 9J, and 9K are exemplary diagrams illustrated according to a process sequence to explain a method of manufacturing a semiconductor package according to example embodiments of the present disclosure.

### DETAILED DESCRIPTION

Before a detailed description of the present disclosure, the terms or words used in this specification and the claims should not be construed as being limited to their general or lexical meanings, and based on the principle that the applicant may properly define the disclosure with a notion of terms in a way that best explains the disclosure, should be interpreted as meanings and notions corresponding to the technical idea of the present disclosure. Accordingly, example embodiments described in this specification and the configurations shown in the drawings represent merely the most desired embodiments of the present disclosure and do not encompass the entire technical idea of the present disclosure. Therefore, at the point of the present application, the possibility of various equivalents and modified examples that may serve as replacements should be understood.

In the description below, a singular expression includes a plural expression unless clearly indicated otherwise in context. Terms such as "comprise or include" or "configure" should be understood as indicating the existence of a feature, number, step, operation, element, component, or combination thereof described in this specification, and the terms do not exclude in advance the existence or the possibility of one or more additional features, numbers, steps, operations, elements, components, or combinations thereof.

Furthermore, in the description below, expressions such as above, upper portion, below, lower portion, side surface, frontside, and backside are expressed based on directions shown in drawings, and when a direction of an object changes, the expressions may be expressed differently. Forms, sizes, and the like of elements in the drawings may be exaggerated for clearer explanation.

Hereinafter, example embodiments according to a technical idea of the present disclosure will be described with reference to accompanying drawings.

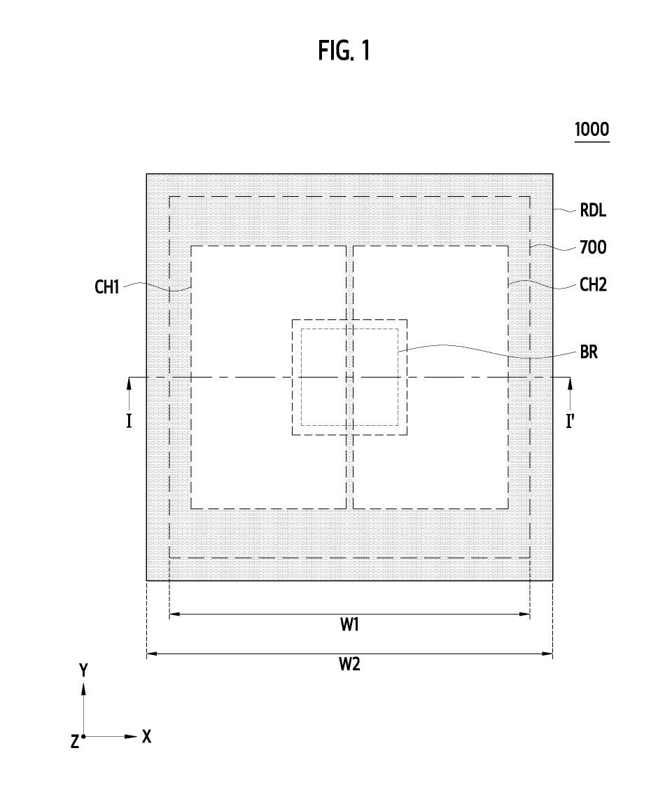

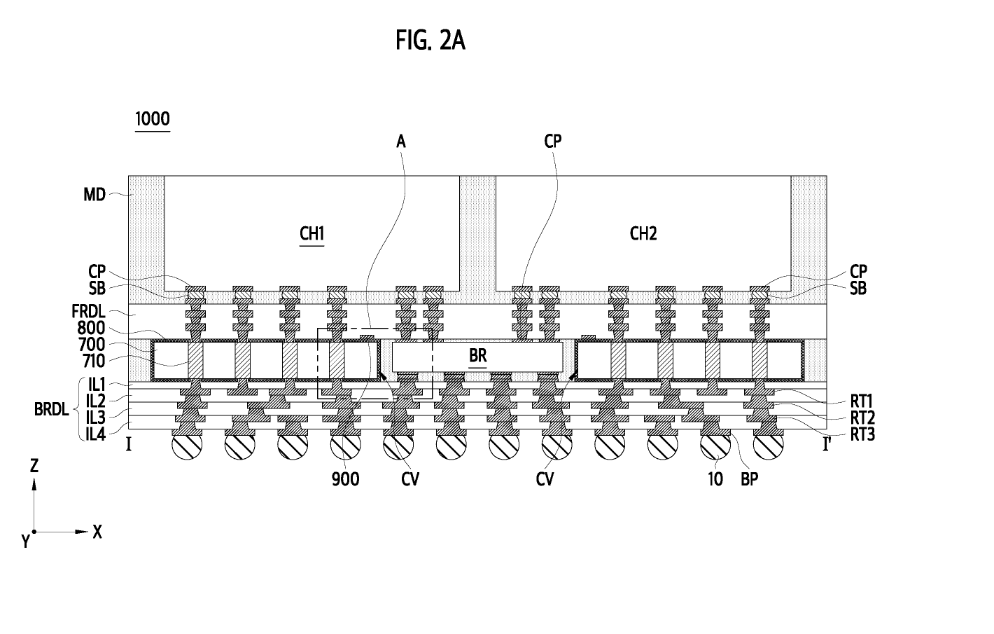

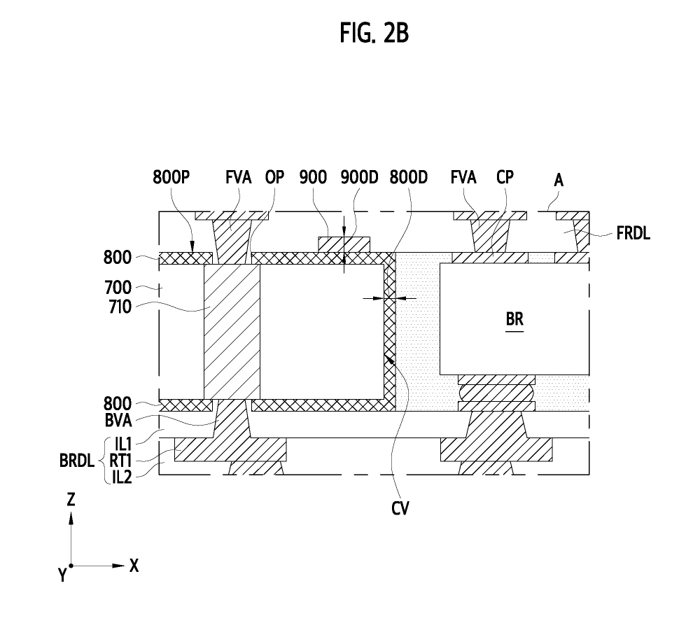

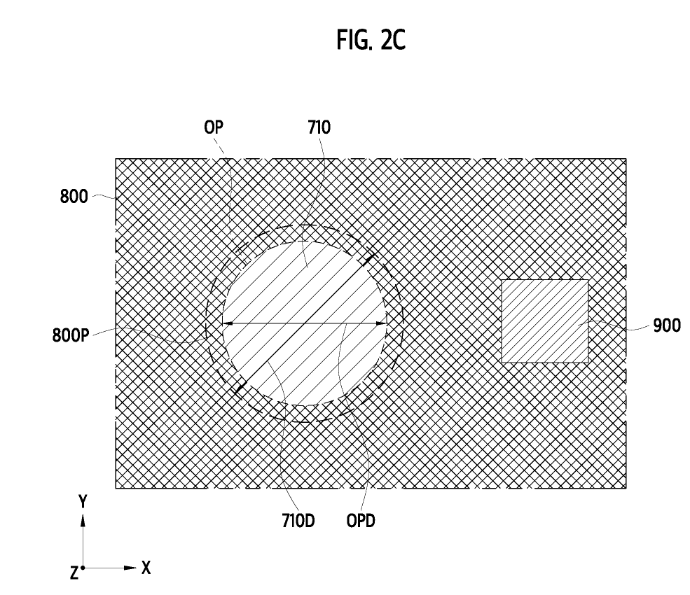

FIG. 1 is a top plan view of a semiconductor package according to example embodiments of the present disclosure. FIG. 2A is an exemplary diagram illustrating a cross section taken along I-I' line of FIG. 1.

Referring to FIGS. 1 and 2A, a semiconductor package 1000 may have a form of a chip-first type fan-out panel level package (FOPLP). The semiconductor package 1000 may be disposed on a lower redistribution substrate BRDL and may include a glass substrate 700 including a cavity region CV, a through via 710 penetrating the glass substrate 700, a thin film layer 800 covering at least a portion of a surface of the glass substrate 700, a bridge die BR disposed within the cavity region CV, an upper redistribution substrate FRDL disposed on the thin film layer 800 and the bridge die BR, and a first semiconductor chip CH1 and a second semiconductor chip CH2 disposed on the upper redistribution substrate FRDL. The semiconductor package 1000 may include a mold layer MD covering at least a portion of the lower redistribution substrate BRDL, the glass substrate 700, the bridge die BR, the upper redistribution substrate FRDL, the first semiconductor chip CH1, and the second semiconductor chip CH2.

According to example embodiments, the glass substrate 700 may have the cavity region CV in the middle and may be disposed on the lower redistribution substrate BRDL. The bridge die BR may be disposed within the cavity region CV. The glass substrate 700 may be extended to a first direction X and a second direction Y parallel to a surface of the glass substrate 700. The glass substrate 700 may have a first width W1 in the first direction X, and the lower redistribution substrate BRDL may have a second width W2 in the first direction X. The second width W2 may be greater than the first width W1.

FIG. 2B is an enlarged view illustrating part A of FIG. 2A. FIG. 2C is a diagram looking from a third direction Z focusing on an opening portion OP of the thin film layer 800 and the through via 710, illustrated with some elements such as the upper redistribution substrate FRDL and an upper connection via FVA omitted.

Referring to FIGS. 2A, 2B, and 2C, a structure of the semiconductor package 1000 will be specifically described.

According to example embodiments, the lower redistribution substrate BRDL may have a first redistribution insulating layer IL1, a second redistribution insulating layer IL2, a third redistribution insulating layer IL3, and a fourth redistribution insulating layer IL4 sequentially stacked. Each of the first redistribution insulating layer IL1, the second redistribution insulating layer IL2, the third redistribution insulating layer IL3, and the fourth redistribution insulating layer IL4 may include a photo imageable dielectric (PID) layer. Alternatively, each of the first redistribution insulating layer IL1, the second redistribution insulating layer IL2, the third redistribution insulating layer IL3, and the fourth redistribution insulating layer IL4 may include a curable insulating layer. A first redistribution pattern RT1 may be interposed between the first redistribution insulating layer IL1 and the second redistribution insulating layer IL2. A second redistribution pattern RT2 may be interposed between the second redistribution insulating layer IL2 and the third redistribution insulating layer IL3. A third redistribution pattern RT3 may be interposed between the third redistribution insulating layer IL3 and the fourth redistribution insulating layer IL4.

According to example embodiments, a lower bonding pad BP may be disposed on a bottom surface of the fourth redistribution insulating layer IL4. The lower bonding pad BP may be in contact with the third redistribution pattern RT3 by penetrating the fourth redistribution insulating layer IL4. A connection terminal 10 may be bonded to the lower bonding pad BP. A connection terminal 10 may be bonded to the lower bonding pad BP. The connection terminal 10 may include at least one of a solder ball, a conductive bump, and a conductive pillar. The connection terminal 10 may include at least one of tin, lead, silver, copper, aluminum, gold, and nickel. According to example embodiments, a structure of the upper redistribution substrate FRDL may be similar to a structure of the lower redistribution substrate BRDL. The lower bonding pad BP and the first to third redistribution patterns RT1, RT2, and RT3 may include a metal such as copper, aluminum, gold, nickel, or titanium.

According to example embodiments, the glass substrate 700 may include the cavity region CV penetrating the central area. The glass substrate 700 may include, for example, SiO₂. The glass substrate 700 may not include wiring.

According to example embodiments, the through via 710 may be electrically connected to the first to third redistribution patterns RT1, RT2, and RT3 of the lower redistribution substrate BRDL. As illustrated in FIG. 2B, the through via 710 may be electrically connected to the lower redistribution substrate BRDL through a lower connection via BVA. The through via 710 may be electrically connected to the upper redistribution substrate FRDL through the upper connection via FVA. In a process of forming the upper connection via FVA, the upper connection via FVA and the through via 710 may be aligned and electrically connected due to a wiring layer 900. The through via 710 may include metal such as copper, aluminum, gold, nickel, or titanium. The glass substrate 700 may have a thickness of 50 micrometer (μm) to 500 μm, but is not limited thereto.

According to example embodiments, the through via 710 may have a structure fully filled with conductive metal and include at least one of, for example, copper (Cu), aluminum, gold, nickel, and titanium. The through via 710 may be electrically connected to the lower redistribution substrate BRDL. A topmost diameter and a bottommost diameter of the through via 710 may be identical, but are not limited thereto.

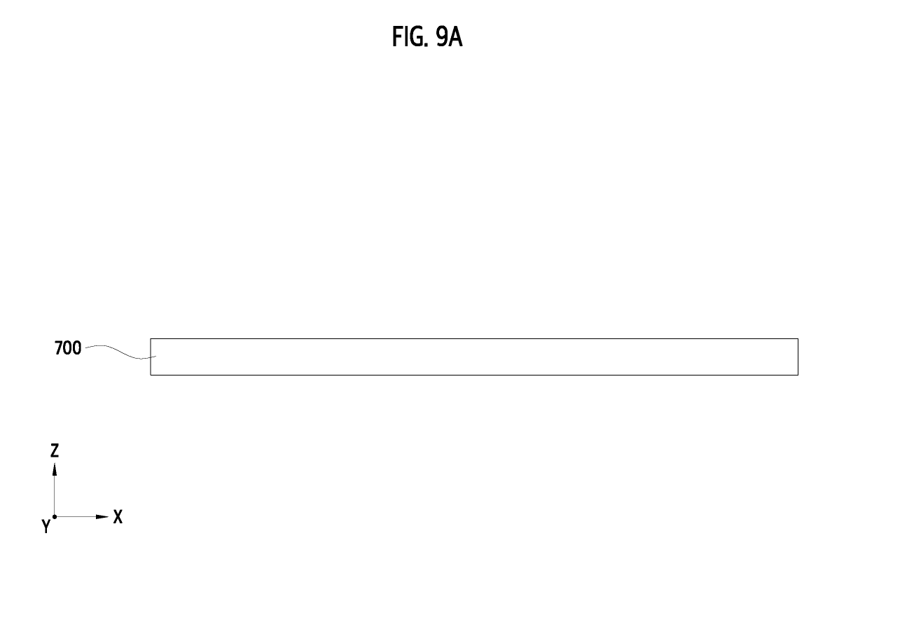

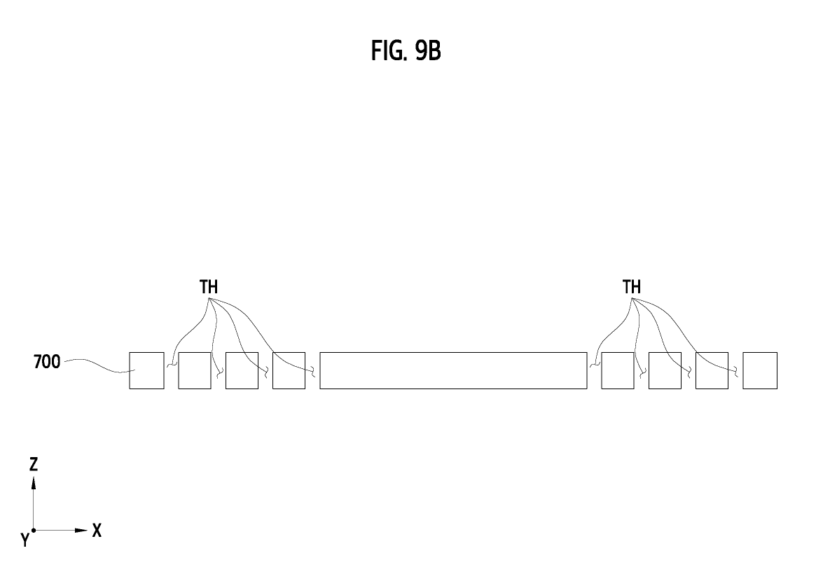

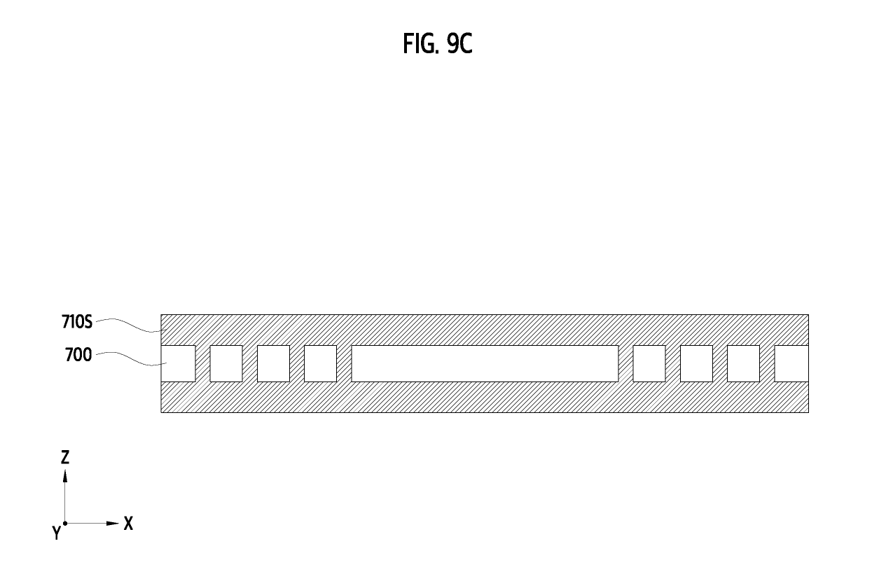

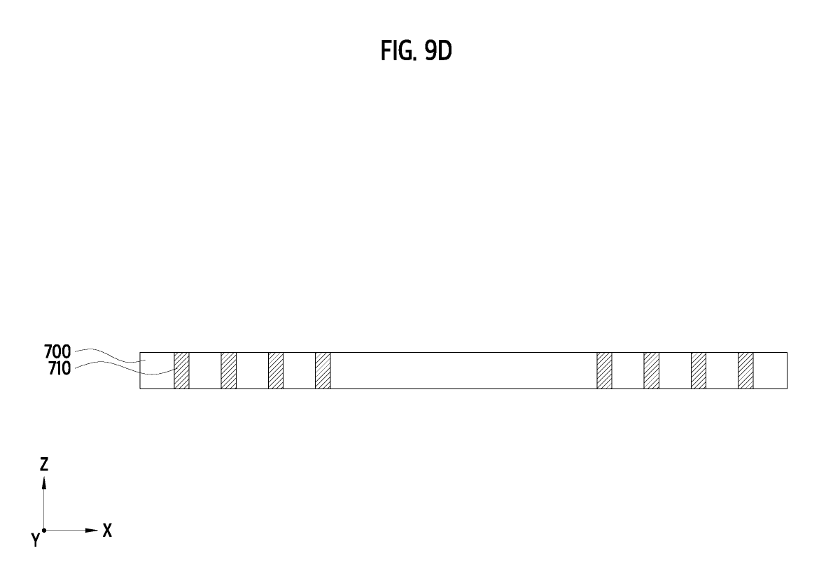

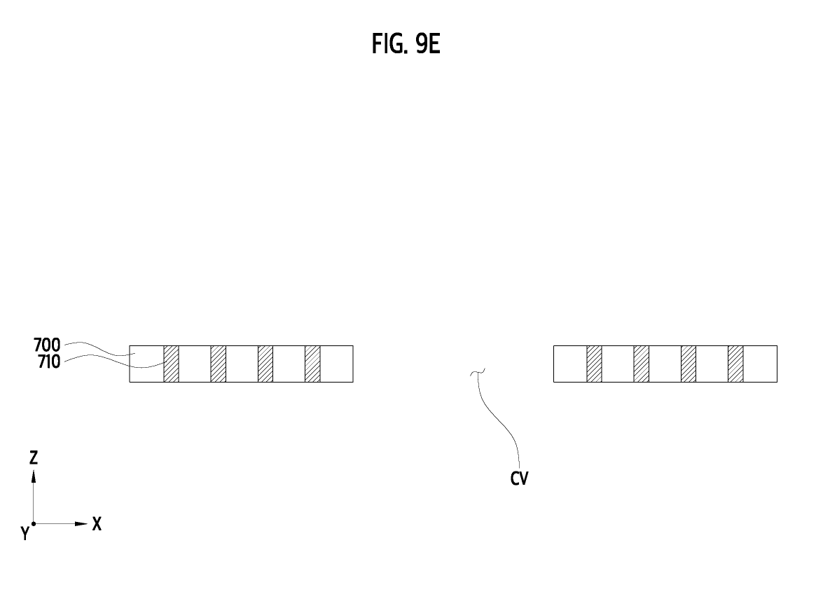

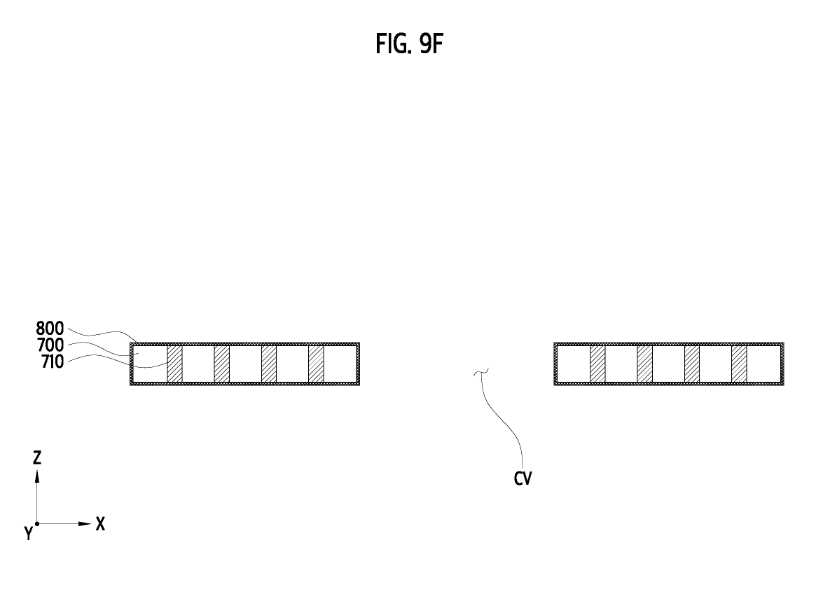

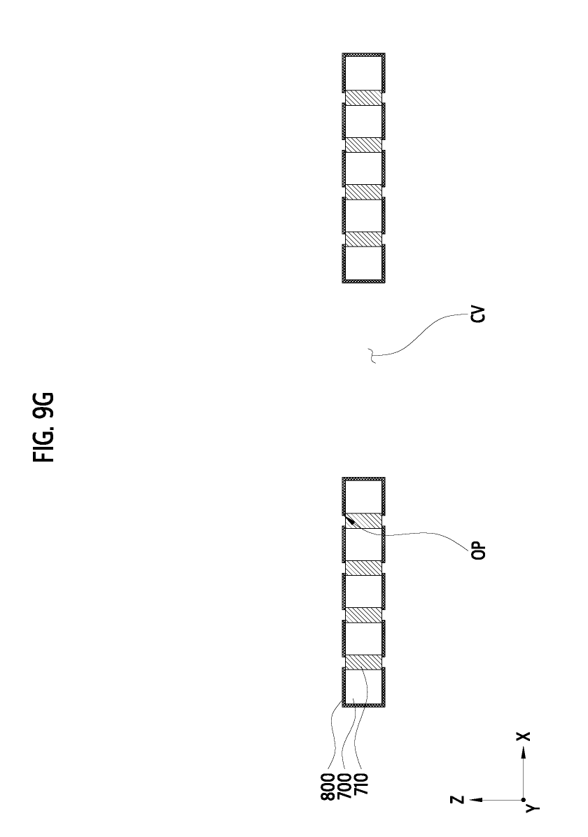

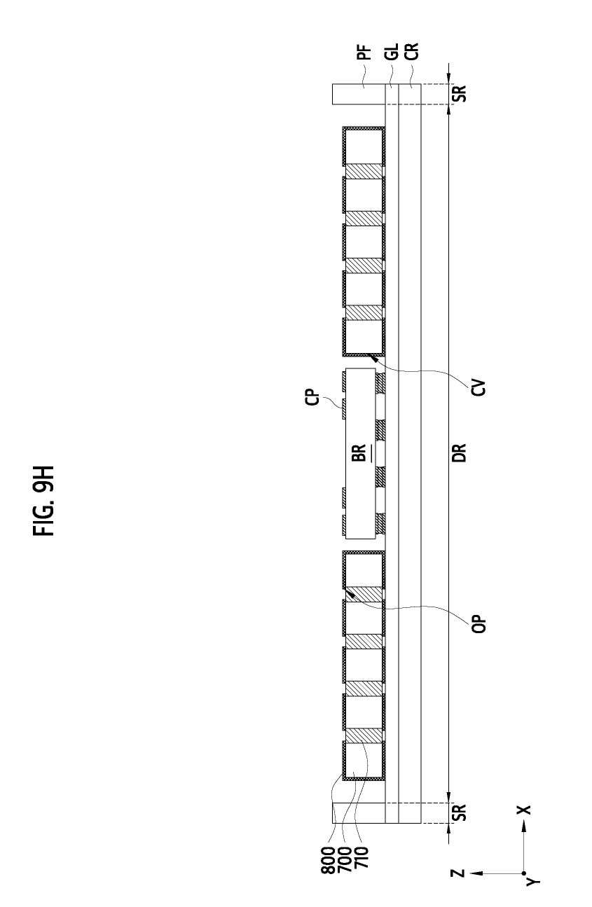

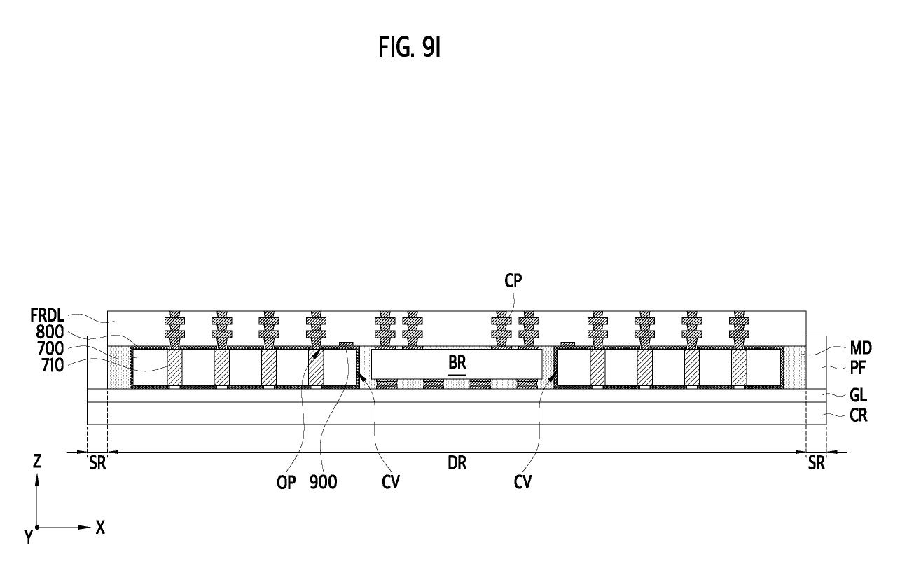

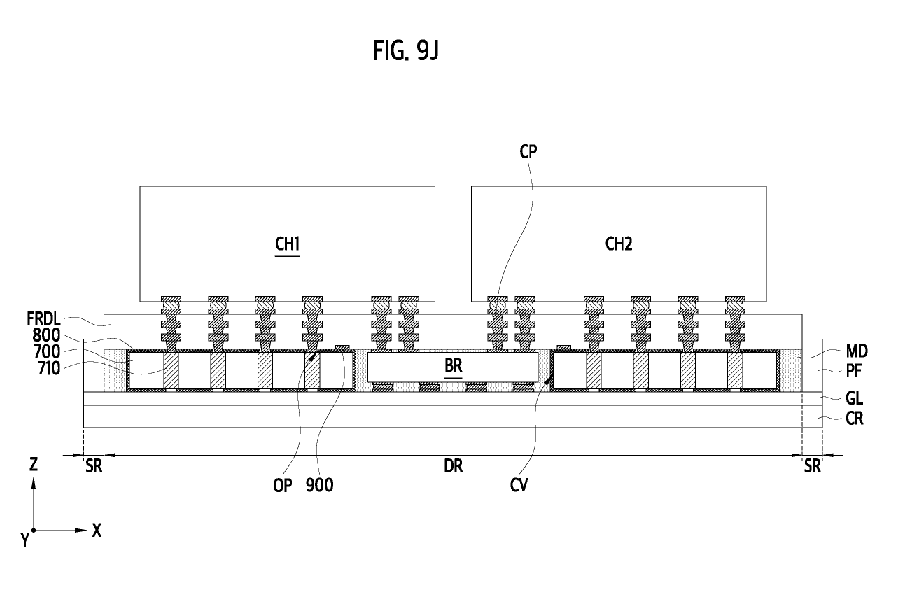

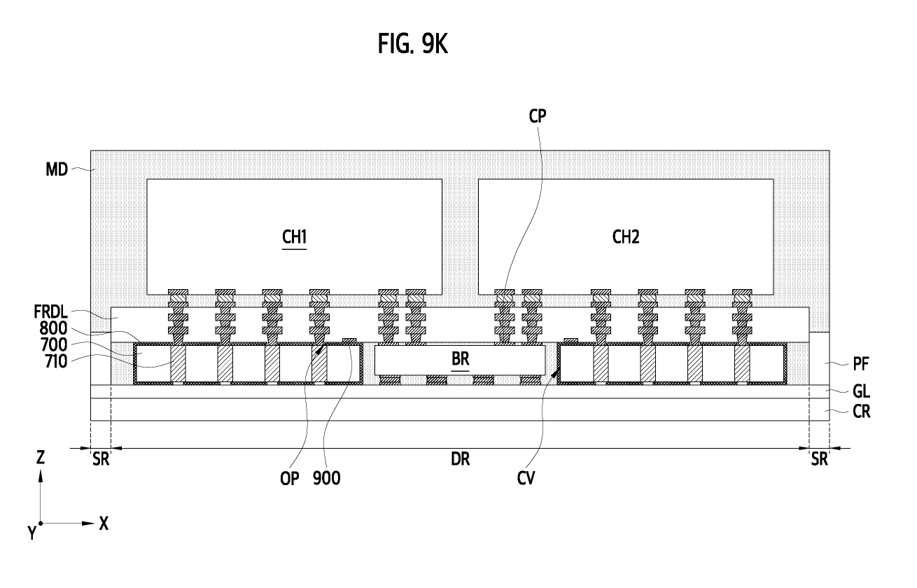

According to example embodiments, a height of the through via 710 along a third direction Z may be substantially identical to a thickness of the glass substrate 700 along the third direction Z. For example, through a chemical mechanical polishing (CMP) process illustrated in FIG. 9D, a top surface of the through via 710 may be on the same level as a top surface of the glass substrate 700, and a bottom surface of the through via 710 may be on the same level as a bottom surface of the glass substrate 700. In other words, the top surface of the through via 710 may be coplanar with the top surface of the glass substrate 700, and the bottom surface of the through via 710 may be coplanar with the bottom surface of the glass substrate 700. The term coplanar may refer to a condition in which surfaces of two or more elements lie on the same plane, or are considered to be substantially on the same plane even if minor surface irregularities exist due to surface treatment processes such as the CMP process. Therefore, the upper connection via FVA of the upper redistribution substrate FRDL and the lower connection via BVA of the lower redistribution substrate BRDL may be in contact with a plane surface of the through via 710, which may improve electrical performance and reliability of the semiconductor package 1000.

According to example embodiments, the thin film layer 800 may be disposed on at least a portion of a surface of the glass substrate 700 and a side wall of the glass substrate 700, which is defined as the cavity region CV. The thin film layer 800 may be formed of an inorganic insulating material including at least one of silicon nitride (SiN), silicon oxide (SiOx), or other metal oxides (for example, ZnO, SnO, or MnO). A thickness of the thin film layer 800 may be, for example, equal to or less than 3 µm, but is not limited thereto. The thin film layer 800 may reinforce adhesion between the glass substrate 700 and an organic insulating layer included in the upper redistribution substrate FRDL stacked on the glass substrate 700, protect the surface of the glass substrate 700, and improve an interfacial property around the through via 710. The thin film layer 800 may reduce delamination and cracking of the glass substrate 700 by ensuring adhesion between the glass substrate 700, the upper redistribution substrate FRDL, and the lower redistribution substrate BRDL. According to example embodiments, it is possible to reduce delamination and cracking of the glass substrate 700 through the thin film layer 800.

According to example embodiments, the opening portion OP, which exposes the top surface and the bottom surface of the through via 710 to be electrically connected to the upper connection via FVA and the lower connection via BVA, may be formed on the thin film layer 800. As illustrated in FIG. 2C, a diameter OPD of the opening portion OP may be equal to or less than a diameter 710D of the through via 710. A portion 800P of the thin film layer 800 may be disposed on an edge area of the top surface or the bottom surface of the through via 710 and may overlap with the through via 710 in the third direction Z.

According to example embodiments, the wiring layer 900 may be formed on the thin film layer 800, spaced apart from the through via 710 and disposed in a direction parallel to the top surface of the glass substrate 700. The wiring layer 900 may be electrically insulated from the upper redistribution substrate FRDL and be formed close to the cavity region CV to be used as an align key when mounting the bridge die BR. A thickness 900D of the wiring layer 900 may be less than 5 μm and greater than a thickness 800D of the thin film layer 800. The wiring layer 900 may improve alignment accuracy when forming the upper connection via FVA through the through via 710.

According to example embodiments, the bridge die BR may be a semiconductor single-crystal substrate or a silicon on insulator (SOI) substrate. Even though not illustrated, the bridge die BR may include a substrate, interlayer insulating layers, and internal wirings. The bridge die BR may not include transistors and a connection via. For example, a thickness of the bridge die BR may be between 0.9 to 1.1 times the thickness of the glass substrate 700.

According to example embodiments, semiconductor chips CH1 and CH2 may include the first semiconductor chip CH1 and the second semiconductor chip CH2. The first semiconductor chip CH1 and the second semiconductor chip CH2 may be arranged in parallel on the upper redistribution substrate FRDL. Each of the first semiconductor chip CH1 and the second semiconductor chip CH2 may be a single semiconductor die, a semiconductor chip, or a semiconductor package including a plurality of homogeneous or heterogeneous semiconductor dies. Each of the first semiconductor chip CH1 and the second semiconductor chip CH2 may be one of an image sensor chip such as a complementary metal-oxide semiconductor (CMOS) imaging sensor (CIS), a memory device chip such as a flash memory chip, a dynamic random-access memory (DRAM) chip, a static random-access memory (SRAM) chip, an electrically erasable programmable read-only memory (EEPROM) chip, a phase-change random-access memory (PRAM) chip, a magnetoresistive random-access memory (MRAM) chip, a resistive random-access memory (ReRAM) chip, a high bandwidth memory (HBM) chip, or a hybrid memory cube (HMC) chip, or a microelectromechanical system (MEMS) device chip, or an application-specific integrated circuit (ASIC) chip. The first semiconductor chip CH1 and the second semiconductor chip CH2 may be identical or different semiconductor chips. Although not illustrated, each of the first semiconductor chip CH1 and the second semiconductor chip CH2 may include a substrate, interlayer insulating layers, and an integrated circuit (transistors and internal wirings).

According to example embodiments, a chip pad CP may be disposed on a top surface of the bridge die BR. The chip pad CP may be disposed on each bottom surface of the first semiconductor chip CH1 and the second semiconductor chip CH2. The chip pad CP may include metal such as copper, aluminum, gold, nickel, or titanium.

According to example embodiments, the upper connection via FVA may connect the bridge die BR to each of the first semiconductor chip CH1 and the second semiconductor chip CH2. The upper connection via FVA may connect the upper redistribution substrate FRDL and the through via 710, and the upper redistribution substrate FRDL and the bridge die BR. The upper connection via FVA may connect the through via 710 to each of the first semiconductor chip CH1 and the second semiconductor chip CH2.

According to example embodiments, an internal connection terminal SB may be disposed between the chip pad CP disposed on bottom surfaces of the first semiconductor chip CH1 and the second semiconductor chip CH2 and the chip pad CP disposed on the upper redistribution substrate FRDL. The internal connection terminal SB may include a solder ball or a conductive bump. The internal connection terminal SB may bond the first semiconductor chip CH1 and the second semiconductor chip CH2 to the upper redistribution substrate FRDL using a flip-chip bonding method.

According to example embodiments, the mold layer MD may cover at least a portion of a top surface of the lower redistribution substrate BRDL, a top surface of the upper redistribution substrate FRDL, the thin film layer 800, the bridge die BR, the first semiconductor chip CH1, and the second semiconductor chip CH2. Specifically, the mold layer MD may cover a side wall of the bridge die BR, a side wall of the thin film layer 800, bottom surfaces and side walls of the first semiconductor chip CH1 and the second semiconductor chip CH2, and a top surface of the lower redistribution substrate BRDL. As at least a portion of the glass substrate 700 may be surrounded by the thin film layer 800, a side wall of the glass substrate 700 may not be exposed, and accordingly, crack formation between the glass substrate 700 and the mold layer MD may be prevented or minimized. Therefore, the semiconductor package 1000 with improved durability may be provided. According to example embodiments, FIG. 2A illustrates that the mold layer MD is not disposed between the thin film layer 800 and the lower redistribution substrate BRDL, but the example embodiment is not limited thereto. For example, the thin film layer 800 and the lower redistribution substrate BRDL may be spaced apart from each other in the third direction Z, and the mold layer MD may be disposed between the thin film layer 800 and the lower redistribution substrate BRDL. In addition, the mold layer MD may cover a side wall of the upper redistribution substrate FRDL.

According to example embodiments, top surfaces of the first semiconductor chip CH1 and the second semiconductor chip CH2 may be coplanar with a top surface of the mold layer MD, but is not limited thereto. The mold layer MD, for example, may include an insulating resin, such as an epoxy molding compound (EMC). The mold layer MD may further include a filler, and the filler may be dispersed within the insulating resin.

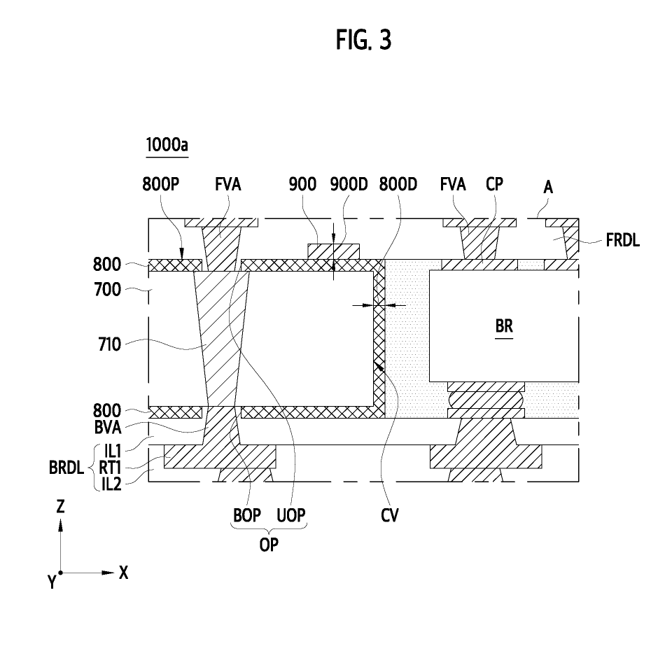

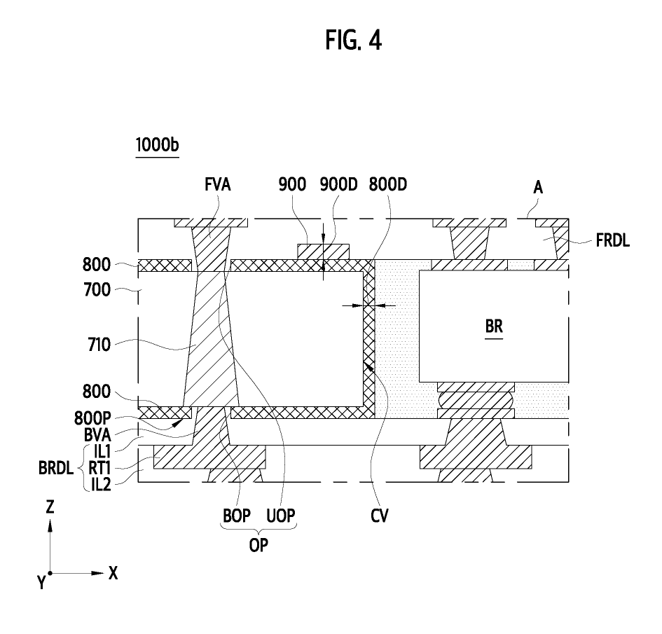

FIG. 3 is a semiconductor package according to example embodiments of the present disclosure and an enlarged view illustrating part A of FIG. 2A. FIG. 4 is a semiconductor package according to example embodiments of the present disclosure and an enlarged view illustrating part A of FIG. 2A.

Referring to FIGS. 3 and 4, a through via 710 in semiconductor packages 1000a and 1000b may be formed in various shapes. According to example embodiments, the through via 710 may have a tapered shape in which a topmost diameter and a bottommost diameter are different. As described later in FIG. 9B, the shape may be controlled by a process condition during forming a through via hole TH.

According to example embodiments, the through via 710 in the semiconductor package 1000a of FIG. 3 may have a topmost diameter wider than a bottommost diameter, while the through via 710 in the semiconductor package 1000b of FIG. 4 may have a topmost diameter narrower than a bottommost diameter.

According to example embodiments, a thin film layer 800 may include an opening portion OP, and the opening portion OP may include an upper opening portion UOP and a lower opening portion BOP. In a process removing a portion of the thin film layer 800, as an area exposing a surface of the through via 710 may be different, a diameter of the upper opening portion UOP and a diameter of the lower opening portion BOP may be different.

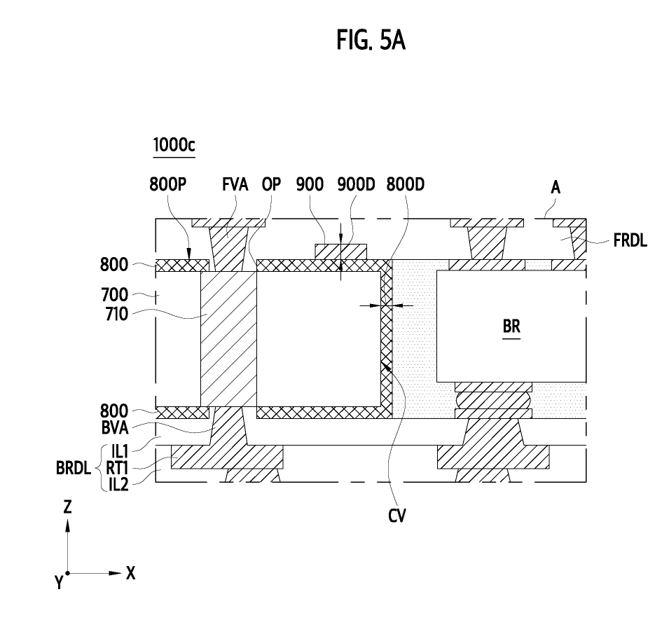

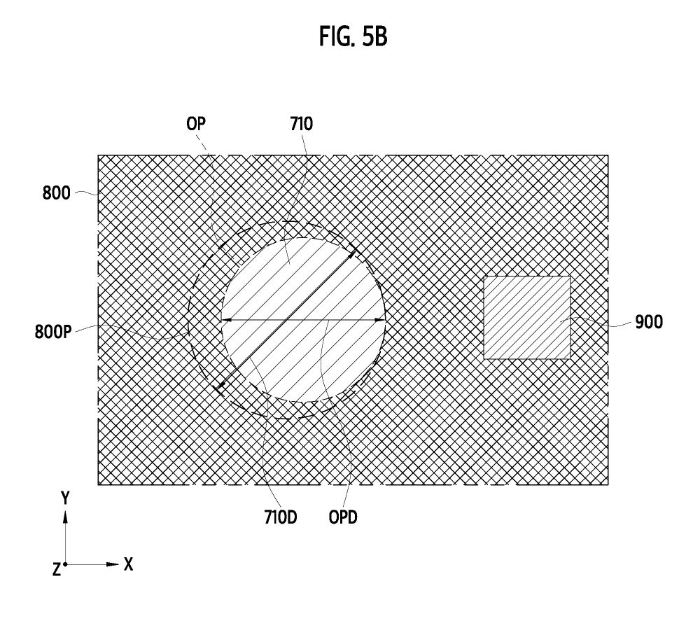

FIG. 5A is a semiconductor package according to example embodiments of the present disclosure and an enlarged view illustrating part A of FIG. 2A. FIG. 5B is a diagram looking from a third direction Z focusing on an opening portion OP of a thin film layer 800 and a through via 710, with some elements such as an upper redistribution substrate FRDL and an upper connection via FVA omitted.

Referring to FIGS. 5A and 5B, an area in which the thin film layer 800 covers a surface of the through via 710 may be different from the one described above in the semiconductor package 1000 of FIG. 2A. The thin film layer 800 may include the opening portion OP, and the through via 710 may be exposed through the opening portion OP. As a diameter OPD of the opening portion OP may be smaller than a diameter 710D of the through via 710, a portion of the thin film layer 800 may vertically overlap with the through via 710. In addition, a wiring layer 900 may be formed on the thin film layer 800 and disposed to be spaced apart from the through via 710 in a direction parallel to a top surface of the glass substrate 700. The center of the opening portion OP may not coincide with the center of the through via 710 and may be offset. The opening portion OP may be located concentrically with the center of the through via 710, and a portion 800P of the thin film layer 800 may vertically overlap with the through via 710 due to the difference between the diameter 710D of the through via 710 and the diameter OPD of the opening portion OP. As such, through a structure in which a portion of the thin film layer 800 vertically overlaps with the through via 710, alignment accuracy between the through via 710, the upper redistribution substrate FRDL, and the lower redistribution substrate BRDL may be improved, and delamination and cracking of the glass substrate 700 may be reduced as the thin film layer 800, an inorganic layer, ensures adhesion between the glass substrate 700, the upper redistribution substrate FRDL, and the lower redistribution substrate BRDL.

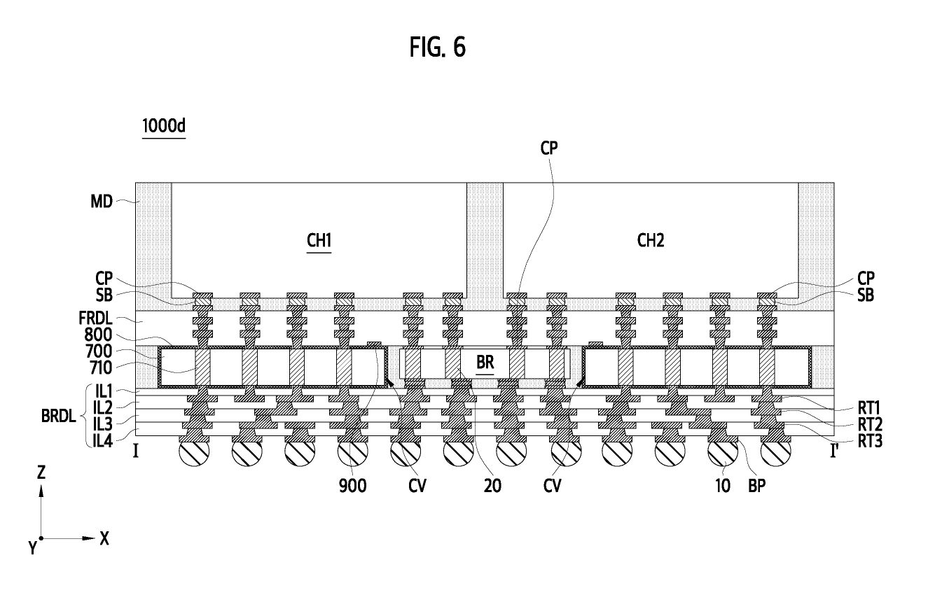

FIG. 6 is a semiconductor package according to example embodiments of the present disclosure and an exemplary diagram illustrating a cross section taken along I-I' line of FIG. 1.

Referring to FIG. 6, a semiconductor package 1000d may have a structure in which the bridge die BR in a structure of FIG. 2A includes a center connection via 20. A first semiconductor chip CH1, an upper redistribution substrate FRDL, and a lower redistribution substrate BRDL may be electrically connected through the center connection via 20. Other configurations may be identical or similar to what is described with reference to FIGS. 1, 2A, 2B, and 2C.

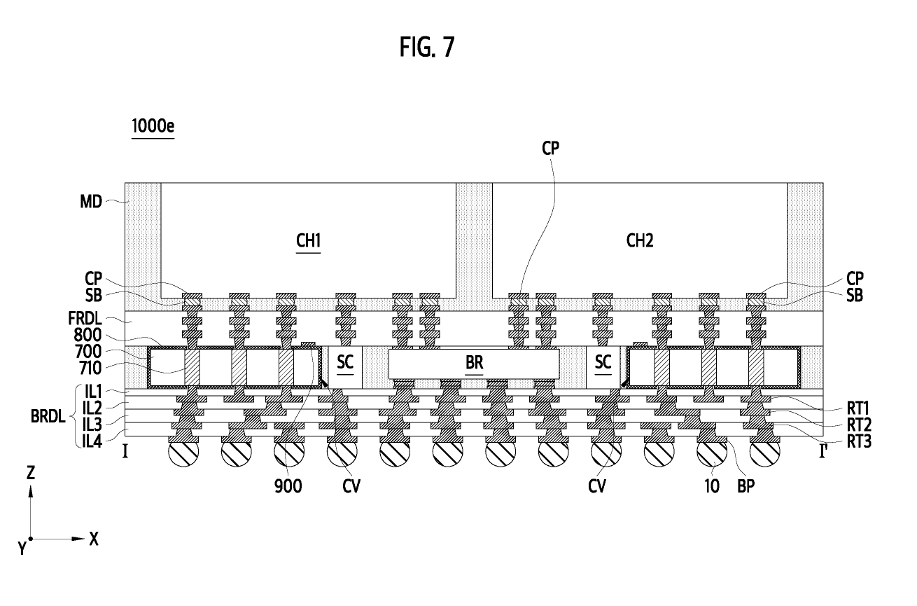

FIG. 7 is a semiconductor package according to example embodiments of the present disclosure and an exemplary diagram illustrating a cross section taken along I-I' line of FIG. 1

Referring to FIG. 7, a semiconductor package 1000e may have a structure in which at least one or more silicon capacitors SC are disposed between the bridge die BR and the glass substrate 700 in the structure of FIG. 2A. A silicon capacitor SC may be located within a cavity region CV between an outer wall of the bridge die BR and an inner wall of the glass substrate 700. The silicon capacitor SC may include silicon (Si). The silicon capacitor SC may include an electrode. Although not illustrated, the silicon capacitor SC may include a chip pad in a top surface and a bottom surface. Other configurations may be identical or similar to what is described with reference to FIGS. 1, 2A, 2B, and 2C.

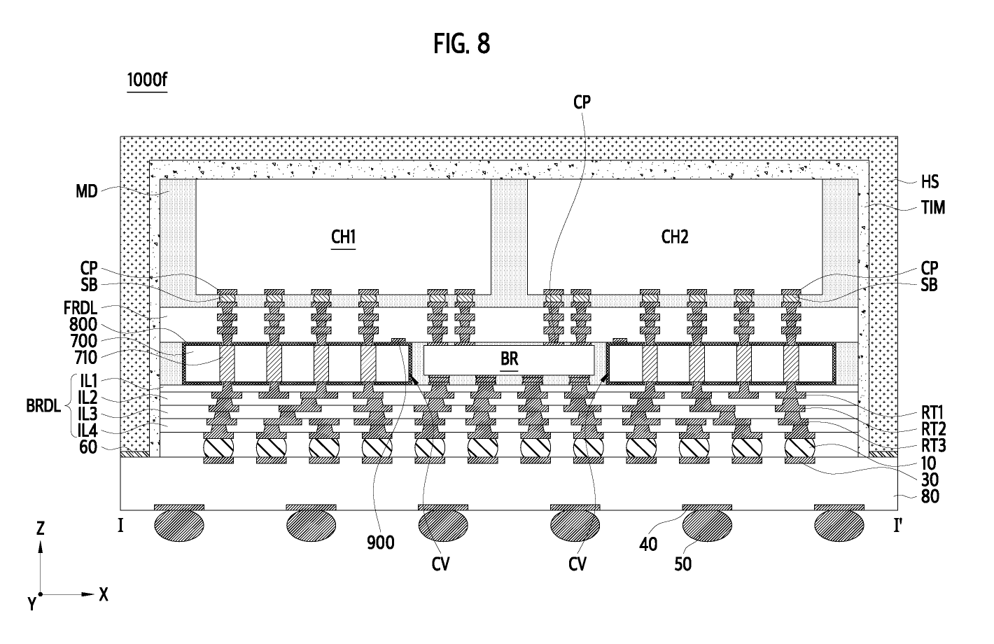

FIG. 8 is a semiconductor package according to example embodiments of the present disclosure and an exemplary diagram illustrating a cross section taken along I-I' line of FIG. 1.

Referring to FIG. 8, a semiconductor package 1000f according to the example embodiments may include a base substrate 80. The base substrate 80 may be a printed circuit board. An upper substrate pad 30 may be disposed on a top surface of the base substrate 80, and a lower substrate pad 40 may be disposed on a bottom surface of the base substrate 80. The semiconductor package 1000f may have a structure in which the semiconductor package 1000 of FIG. 2A is mounted on the base substrate 80. A connection terminal 10 may be bonded to the upper substrate pad 30. An outer connection terminal 50 may be bonded to the lower substrate pad 40. The outer connection terminal 50 may include at least one of a solder ball, a conductive bump, and a conductive pillar. The outer connection terminal 50 may include at least one of tin, lead, silver, copper, aluminum, gold, and nickel.

According to example embodiments, a heat dissipation member HS covering a top surface of the base substrate 80, a first semiconductor chip CH1, a second semiconductor chip CH2, and a mold layer MD may be provided. The heat dissipation member HS may be made of a material having excellent thermal conductivity and may include, for example, a metal or graphene.

According to example embodiments, a thermal interface material TIM may be interposed between the heat dissipation member HS and the mold layer MD, between the heat dissipation member HS and the first semiconductor chip CH1, and between the heat dissipation member HS and the second semiconductor chip CH2. The thermal interface material TIM may include a thermosetting resin layer. The thermal interface material TIM may further include pillar particles dispersed within the thermosetting resin layer. The pillar particles may include at least one of silica, alumina, zinc oxide, and boron nitride. An adhesive layer 60 may be disposed between the heat dissipation member HS and the base substrate 80. The adhesive layer 60 may include an identical material to the thermal interface material TIM. Other configurations may be identical or similar to what is described with reference to FIGS. 1, 2A, 2B, 2C, 3, 4, 5A, 5B, 6, and 7.

FIGS. 9A, 9B, 9C, 9D, 9E, 9F, and 9G are exemplary diagrams illustrated according to a process sequence to explain a method of manufacturing some elements of a semiconductor package according to example embodiments of the present disclosure. FIGS. 9H, 9I, 9J and 9K are exemplary diagrams illustrated according to a process sequence to explain a method of manufacturing a semiconductor package according to example embodiments of the present disclosure. Hereinafter, descriptions overlapping with the above may be omitted.

Referring to FIG. 9A, a glass substrate 700 may be provided.

According to example embodiments, a size of the glass substrate 700 may vary.

Referring to FIG. 9B, forming the through via hole TH penetrating the glass substrate 700 may be performed.

According to example embodiments, a through via hole TH may be formed through a laser drilling process or an etching process, but is not limited thereto. According to example embodiments, the through via hole TH may have a tapered shape in which a diameter of an upper portion is greater than a diameter of a lower portion, but is not limited thereto. Accordingly, a through via 710 described later may have various shapes as with the through via 710 of FIGS. 3 and 4.

Referring to FIG. 9C, a preliminary through via layer 710S may be formed to cover a top surface and a bottom surface of the glass substrate 700 and to fill the through via hole TH.

According to example embodiments, a Cu layer may be formed through electroplating. For example, before the process of forming the preliminary through via layer 710S, a process of forming a separate seed metal layer may be performed. The preliminary through via layer 710S may entirely fill the inside of the through via hole TH and may be formed on the top surface and the bottom surface of the glass substrate 700.

Referring to FIG. 9D, as a portion of the preliminary through via layer 710S is removed, a through via 710 may be formed.

According to example embodiments, through a grinding and/or a polishing process, as the preliminary through via layer 710S on the top surface and the bottom surface of the glass substrate 700 is removed, the through via 710 that entirely fills the inside of the through via hole TH may be formed. For example, by removing the preliminary through via layer 710S on the top surface and the bottom surface of the glass substrate 700 through the CMP process, a top surface of the through via 710 may be coplanar with the top surface of the glass substrate 700, and a bottom surface of the through via 710 may be coplanar with the bottom surface of the glass substrate 700. Accordingly, a height of the through via 710 along a third direction Z may be substantially identical to a thickness of the glass substrate 700 along the third direction Z. The third direction Z may refer to a direction that crosses the top surface of the glass substrate 700. If a cavity region CV is not formed in a previous process, the cavity region CV may be formed in a portion corresponding to a central portion of the glass substrate 700 after the through via 710 is formed.

Referring to FIG. 9E, the cavity region CV may be formed by penetrating a portion of the glass substrate 700.

According to example embodiments, the cavity region CV is a space for embedding a bridge die BR in a subsequent process and may be formed through a laser drilling or an etching process. Subsequently, the glass substrate 700 may be completed by singulating the glass substrate 700 through a sawing process. The singulation process may be performed using a dicing blade or a laser cutting method.

Referring to FIG. 9F, a thin film layer 800, covering at least a portion of the glass substrate 700 and the through via 710, may be formed.

According to example embodiments, the thin film layer 800 may be formed on the top surface and the bottom surface of the through via 710, on the top surface and the bottom surface of the glass substrate 700, and on a side wall of the glass substrate 700, defined as the cavity region CV.

According to example embodiments, the thin film layer 800 may be formed of an inorganic layer including at least one of silicon nitride (SiN), silicon oxide (SiOx), or other metal oxides (for example, ZnO, SnO, or MnO). The inorganic layer may be formed by a chemical vapour deposition process or a sputtering method, and may be formed with a thickness of 3 μm or less. The thin film layer 800 may improve adhesion between the glass substrate 700 and an upper redistribution substrate FRDL and a lower redistribution substrate BRDL in a subsequent process.

Referring to FIG. 9G, an opening portion OP may be formed as at least a portion of the thin film layer 800 is removed to expose at least a portion of the surface of the through via 710.

According to example embodiments, the thin film layer 800 may form the opening portion OP that exposes the top surface and the bottom surface of the through via 710. A diameter of the opening portion OP may be equal to or less than a diameter of the through via 710. Accordingly, in a subsequent process of forming the upper redistribution substrate FRDL, the alignment and arrangement of the through via 710 and the upper redistribution substrate FRDL may be improved. In addition, as the thin film layer 800 ensures adhesion and bonding strength between the glass substrate 700 and the upper redistribution substrate FRDL, delamination and cracking of the glass substrate 700 may be reduced. According to example embodiments, a portion of the thin film layer 800 may be disposed on the top surface or the bottom surface of the through via 710 and may have a structure vertically overlapping with the through via 710.

According to example embodiments, as illustrated in FIGS. 3 and 4, the opening portion OP may include the upper opening portion UOP exposing at least a portion of the top surface of the through via 710 and the lower opening portion BOP exposing at least a portion of the bottom surface of the through via 710, and a diameter of the upper opening portion UOP may be different from a diameter of the lower opening portion BOP.

Referring to FIG. 9H, a bridge die BR may be formed within the cavity region CV.

According to example embodiments, a carrier substrate CR may be disposed, and a carrier bonding layer GL may be disposed on the carrier substrate CR. For example, the carrier bonding layer GL may include adhesive resin, thermosetting resin, thermoplasitc resin, and photocurable resin. The carrier substrate CR may include a plurality of separation area SR and a chip area DR therebetween. A panel frame PF may be disposed on the carrier bonding layer GL. The panel frame PF may be disposed to overlap with the separation area SR and may have a form of surrounding the chip area DR. The panel frame PF may have a grid shape in a planar view, but is not limited thereto.

According to example embodiments, the glass substrate 700 including the cavity region CV may be provided. At least a portion of the glass substrate 700 may be penetrated by the through via 710. At least a portion of the glass substrate 700 may be surrounded by the thin film layer 800, and the thin film layer 800 may be bonded to the carrier bonding layer GL. The glass substrate 700 may be disposed to be spaced apart from the panel frame PF. The glass substrate 700 may be identical or similar to the glass substrate 700 described with reference to FIGS. 1, 2A, 2B, and 2C. According to example embodiments, as the thin film layer 800 is disposed on the top surface, the bottom surface, and the side surface of the glass substrate 700, the glass substrate 700 may be flipped to bond either a top portion or a bottom portion of the glass substrate 700 onto the carrier bonding layer GL. Accordingly, the shape of the through via 710 of FIGS. 3-4 may be disposed as needed, which may reduce the level of difficulty in a manufacturing process. According to example embodiments, the manufacturing process of the semiconductor package 1000 may be performed in a state in which the glass substrate 700 is disposed on the lower redistribution substrate BRDL.

According to example embodiments, the bridge die BR may be provided. The bridge die BR may be formed in an identical thickness to the glass substrate 700, but is not limited thereto. For example, a thickness of the bridge die BR may be between 0.9 to 1.1 times a thickness of the glass substrate 700. The bridge die BR may be bonded within the cavity region CV of the glass substrate 700. The bridge die BR may be disposed to be spaced apart from the glass substrate 700. The bridge die BR may be identical or similar to the bridge die BR described with reference to FIGS. 1, 2A, 2B, and 2C.

Referring to FIG. 9I, a mold layer MD, a wiring layer 900, and an upper redistribution substrate FRDL covering at least a portion of the glass substrate 700 and the thin film layer 800 may be formed.

According to example embodiments, the wiring layer 900 may be formed on the thin film layer 800. A thickness of the wiring layer 900 may be greater than a thickness of the thin film layer 800. For example, the thickness of the wiring layer 900 may be formed to be 5 μm or less, which may enhance optical recognition in a subsequent process or facilitate probe contact when necessary.

According to example embodiments, the wiring layer 900 may be adjacent to the cavity region CV and may serve as an align key when embedding the bridge die BR. For example, the wiring layer 900 may be formed around the cavity region CV of the glass substrate 700 or at a predetermined location and used as a reference to accurately position and mount the bridge die BR, the first semiconductor chip CH1, or the second semiconductor chip CH2 on the glass substrate 700. According to example embodiments, it is possible to improve the reliability of the semiconductor package 1000 by enhancing embedding accuracy of the bridge die BR within the cavity region CV and securing adhesion between the glass substrate 700 and the upper redistribution substrate FRDL through the thin film layer 800 surrounding at least a portion of a surface of the glass substrate 700.

According to example embodiments, the upper redistribution substrate FRDL may be configured with one or more insulation layers and wiring patterns formed therebetween and may be manufactured using a build-up method. The wiring of the upper redistribution substrate FRDL may be electrically connected to the top surface of the through via 710 exposed through the opening portion OP formed on the through via 710 of the glass substrate 700 and also electrically connected to upper terminals of the bridge die BR. At this point, the wiring layer 900 formed on the thin film layer 800 may be disposed to be spaced apart from the through via 710 in a direction parallel to the top surface of the glass substrate 700 and electrically insulated from the upper redistribution substrate FRDL. Depending on a design, the wiring layer 900 may be additionally formed around the cavity region CV as needed to perform an auxiliary function such as providing a reference potential, or signal routing.

Referring to FIG. 9J, a first semiconductor chip CH1 and a second semiconductor chip CH2 may be formed on the upper redistribution substrate FRDL.

According to example embodiments, the first semiconductor chip CH1 and the second semiconductor chip CH2 may be provided. The first semiconductor chip CH1 and the second semiconductor chip CH2 may be identical or similar to the first semiconductor chip CH1 and the second semiconductor chip CH2 described with reference to FIGS. 1, 2A, 2B, and 2C. The first semiconductor chip CH1 and the second semiconductor chip CH2 may have the same thickness, but is not limited thereto. Each of the first semiconductor chip CH1 and the second semiconductor chip CH2 may be bonded to the bridge die BR and the glass substrate 700 using a flip-chip bonding method.

Referring to FIG. 9K, a mold layer MD, which covers at least a portion of the first semiconductor chip CH1 and the second semiconductor chip CH2 may be formed.

According to example embodiments, using a molding process, the mold layer MD, which covers at least a portion of the first semiconductor chip CH1, the second semiconductor chip CH2, the upper redistribution substrate FRDL, and the panel frame PF, may be formed. According to example embodiments, the mold layer MD may cover a side wall of the upper redistribution substrate FRDL and at least a portion of the thin film layer 800. Subsequently, using a polishing process or an etch-back process, at least a portion of the mold layer MD may be removed to expose the top surfaces of the first semiconductor chip CH1, the second semiconductor chip CH2, and the mold layer MD.

Next, referring to FIG. 2A together, the carrier bonding layer GL and the carrier substrate CR may be removed to form the lower redistribution substrate BRDL.

According to example embodiments, the lower redistribution substrate BRDL may be formed below the glass substrate 700, the thin film layer 800, the bridge die BR, and the mold layer MD. The lower redistribution substrate BRDL may include a plurality of separation area SR and a chip area DR therebetween. To form the lower redistribution substrate BRDL, the structure of FIG. 9K in which the carrier bonding layer GL and the carrier substrate CR are removed may be flipped so that the bottom surfaces of the glass substrate 700, the bridge die BR, and the mold layer MD face upward. The first redistribution insulating layer IL1 may be formed on the glass substrate 700, the bridge die BR, and the mold layer MD. By patterning the first redistribution insulating layer IL1, via holes may be formed. By forming a conductive layer on the first redistribution insulating layer IL1, the via holes may be filled, and by patterning the conductive layer, the first redistribution pattern RT1 may be formed. By repeating the process, the lower redistribution substrate GRDL, which includes the second to fourth redistribution insulating layers IL2, IL3, and IL4, the second and third redistribution patterns RT2 and RT3, and the lower bonding pad BP, may be formed, and the product may be flipped again. Subsequently, a connection terminal 10 may be bonded to the lower bonding pad BP.

According to example embodiments, by performing a dicing process using a laser and the like, a portion of the lower redistribution substrate BRDL, the panel frame PF, and the mold layer MD in the separation area SR may be removed, and the semiconductor package 1000 may be formed. As a result, the semiconductor package 1000 of FIG. 2A may be formed. Therefore, through the structure in which the through via 710 filling the inside of the through via hole TH and the thin film layer 800 are combined, the bridge die BR may be accurately disposed on the cavity region CV when mounting, and the bending issue of the glass substrate 700 may be resolved, and the first semiconductor chip CH1 and the second semiconductor chip CH2 may be precisely aligned, and strong adhesion may be ensured between the thin film layer 800, the upper redistribution substrate FRDL, and the lower redistribution substrate BRDL.

According to aspects, there is provided a method of manufacturing a semiconductor package, the method comprising forming a through via hole penetrating a glass substrate, forming a through via by filling the through via hole, forming a cavity region by penetrating at least a portion of the glass substrate, forming a thin film layer covering at least a portion of the through via and the glass substrate, forming an opening portion exposing at least a portion of a top surface and a bottom surface of the through via by removing a portion of the thin film layer, forming a bridge die within the cavity region, forming a redistribution substrate on the glass substrate and the bridge die, and forming a semiconductor chip on the redistribution substrate.

According to aspects, there is provided a method of manufacturing a semiconductor package, wherein the forming of the opening portion includes the opening portion having a diameter that is equal to or less than a diameter of the through via.

According to aspects, there is provided a method of manufacturing a semiconductor package, wherein the forming of the thin film layer includes surrounding a top surface, a bottom surface, and a side surface of the glass substrate.

According to aspects, there is provided a method of manufacturing a semiconductor package, the method further comprising forming a wiring layer on the thin film layer before the forming of the redistribution substrate.

According to aspects, there is provided a method of manufacturing a semiconductor package, wherein the forming of the wiring layer includes disposing the wiring layer spaced apart from the through via in a direction parallel to a top surface of the glass substrate.

According to aspects, there is provided a method of manufacturing a semiconductor package, wherein a thickness of the wiring layer is greater than a thickness of the thin film layer.

According to aspects, there is provided a method of manufacturing a semiconductor package, wherein the forming of the redistribution substrate includes forming an upper redistribution substrate disposed on a top surface of the glass substrate and a lower redistribution substrate disposed on a bottom surface of the glass substrate.

According to aspects, there is provided a method of manufacturing a semiconductor package, wherein the forming of the through via includes identically forming a height of the through via in a direction that crosses a top surface of the glass substrate and a thickness of the glass substrate in a direction that crosses the top surface of the glass substrate.

According to aspects, there is provided a method of manufacturing a semiconductor package, wherein the forming of the through via comprises filling the through via hole and forming a preliminary through via layer covering a top surface and a bottom surface of the glass substrate, and removing the preliminary through via layer covering the top surface and the bottom surface of the glass substrate to allow the top surface of the through via to be coplanar with the top surface of the glass substrate, and the bottom surface of the through via to be coplanar with the bottom surface of the glass substrate.

While some example embodiments of the present disclosure are explained in detail above, it is to be understood by those of ordinary skill in the art that the scope of a right of the present disclosure is not limited thereto, but, on the contrary, is intended to cover various modifications and equivalent arrangements included within the spirit and scope of the appended claims. In addition, some elements in aforementioned example embodiments may be deleted to be embodied, and each example embodiment may be combined to be embodied.

What is claimed is:

1. A semiconductor package, comprising:
a glass substrate including a cavity region;
a through via penetrating the glass substrate;
a thin film layer covering at least a portion of a surface of the glass substrate;
a redistribution substrate disposed on the thin film layer; and
a semiconductor chip disposed on the redistribution substrate,
wherein the thin film layer includes an opening portion exposing a top surface of the through via and a bottom surface of the through via, and
wherein a diameter of the opening portion is equal to or less than a diameter of the through via.

2. The semiconductor package of claim 1, wherein a portion of the thin film layer is disposed on the top surface of the through via or the bottom surface of the through via.

3. The semiconductor package of claim 1, wherein the thin film layer includes at least one of silicon nitride, silicon dioxide, and metal oxide.

4. The semiconductor package of claim 1, wherein a height of the through via along a direction that crosses a top surface of the glass substrate is equal to a thickness of the glass substrate along the direction that crosses the top surface of the glass substrate.

5. The semiconductor package of claim 1,
wherein the opening portion comprises:
an upper opening portion exposing at least a portion of the top surface of the through via; and
a lower opening portion exposing at least a portion of the bottom surface of the through via, and
wherein a diameter of the upper opening portion is different from a diameter of the lower opening portion.

6. The semiconductor package of claim 1, further comprising a bridge die disposed within the cavity region,
wherein the redistribution substrate includes an upper redistribution substrate disposed on a top surface of the thin film layer, and
wherein the upper redistribution substrate is configured to electrically connect the bridge die to the semiconductor chip.

7. The semiconductor package of claim 6, further comprising a wiring layer disposed between the thin film layer and the upper redistribution substrate,
wherein the wiring layer is electrically insulated from the upper redistribution substrate and disposed to be spaced apart from the through via in a direction parallel to a top surface of the glass substrate.

8. The semiconductor package of claim 7, wherein a thickness of the wiring layer is greater than a thickness of the thin film layer.

9. A semiconductor package, comprising:
a lower redistribution substrate;
a glass substrate disposed on the lower redistribution substrate and including a cavity region;
a through via penetrating the glass substrate;
a thin film layer covering at least a portion of a surface of the glass substrate;
a bridge die disposed within the cavity region;
an upper redistribution substrate disposed on the thin film layer and the bridge die;
a semiconductor chip disposed on the upper redistribution substrate; and
a mold layer covering at least a portion of the lower redistribution substrate, the glass substrate, the bridge die, the upper redistribution substrate, and the semiconductor chip,
wherein a portion of the thin film layer is disposed on a side wall of the cavity region, and
wherein the thin film layer includes an opening portion exposing at least a portion of the through via.

10. The semiconductor package of claim 9, wherein a diameter of the opening portion is equal to or less than a diameter of the through via.

11. The semiconductor package of claim 9, wherein the mold layer covers the thin film layer disposed on the side wall of the cavity region.

12. The semiconductor package of claim 9, wherein the upper redistribution substrate is electrically connected to the through via.

13. The semiconductor package of claim 9, wherein a portion of the thin film layer vertically overlaps with the through via.

14. The semiconductor package of claim 9, wherein the thin film layer is in contact with a top surface of the lower redistribution substrate.

15. The semiconductor package of claim 9, further comprising a wiring layer disposed on the thin film layer.

16. The semiconductor package of claim 15, wherein the wiring layer is disposed to be spaced apart from the through via in a direction parallel to a top surface of the glass substrate.

17. The semiconductor package of claim 15, wherein the wiring layer is electrically insulated from the upper redistribution substrate.

18. A semiconductor package, comprising:
a base substrate;
a lower redistribution substrate disposed on the base substrate;
a glass substrate disposed on the lower redistribution substrate and including a cavity region;
a through via penetrating the glass substrate;
a thin film layer disposed on a surface of the glass substrate and covering at least a portion of the glass substrate;
a wiring layer disposed on the thin film layer and spaced apart from the through via in a direction parallel to a top surface of the glass substrate;
a bridge die disposed within the cavity region;
an upper redistribution substrate disposed on the thin film layer and the bridge die;
a semiconductor chip disposed on the upper redistribution substrate;
a mold layer covering at least a portion of the lower redistribution substrate, the glass substrate, the bridge die, the upper redistribution substrate, and the semiconductor chip; and
a heat dissipation member covering at least one of a top surface of the base substrate, the semiconductor chip, and the mold layer, and
wherein the thin film layer includes an opening portion exposing at least a portion of a surface of the through via.

19. The semiconductor package of claim 18, wherein a diameter of the opening portion is equal to or less than a diameter of the through via.

20. The semiconductor package of claim 18, wherein a portion of the thin film layer vertically overlaps with the through via.
